(19) United States
(12) Patent Application Publication
(10) Pub. No.: US 2024/0403515 A1
(43) Pub. Date: Dec. 5, 2024

(54) METHOD FOR CREATING A REST MODEL FOR A SIMULATION SYSTEM

(71) Applicant: dSPACE GmbH, Paderborn (DE)

(72) Inventor: Tobias Sielhorst, Paderborn (DE)

(21) Appl. No.: 18/675,234

(22) Filed: May 28, 2024

(30) Foreign Application Priority Data
May 31, 2023 (EP) 23176385.5

(51) Int. Cl. G06F 30/20

(52) U.S. Cl. CPC G06F 30/20

(57) ABSTRACT

A method for creating a rest model for a simulation system having a plurality of submodels includes: selecting at least one submodel as a target model that is not to be included in the rest model; detecting ports of the simulation system that are to be linked to ports of the target model; creating ports in the rest model that correspond to the detected ports and have identical properties; detecting field buses of the simulation system that are to be linked to the target model; and creating field bus controllers in the rest model, wherein the field bus controllers correspond to the detected field buses.

### CROSS-REFERENCE TO PRIOR APPLICATIONS

This application claims benefit to European Patent Application No. EP 23176385.5, filed on May 31, 2023, which is hereby incorporated by reference herein.

### FIELD

The invention relates to a method for creating a rest model for a simulation system having a plurality of submodels.

### BACKGROUND

A virtual control unit, or V-ECU, is a piece of software that simulates an actual control unit or part of an actual control unit in a simulation scenario. There are various V-ECU versions covering a large range of variants—from very simple versions through to a complete version that includes all the components of a real control unit. The simplest form of a V-ECU has just one component for each function. In simplified modeling, for example, a V-ECU includes just one application software component, and both the driver and the various underlying layers of the operating system are abstracted. In a more complex version, the V-ECU includes a plurality of linked software components, for example the entire functionality of a control unit. In the automotive sector, this also includes, for example, the AUTOSAR Runtime Environment (RTE) and the operating system for realistic task scheduling. If required, selected software components can be added in order to simulate the bus communication or the non-volatile random access memory (NVRAM). A V-ECU becomes even more realistic if the actual base software code that is also used in the production code is added. Therefore, a V-ECU includes components of application and base software, thus offering functionalities that are comparable with those of actual control units. It is used, for example, for validation during a computer-based simulation.

Since real control unit hardware is not used when using a V-ECU, the simulation can be carried out more quickly than in real time, and so the simulated control unit can be analyzed very quickly and conveniently. By using software-in-the-loop (SIL) tests in computer-based simulations, software functions, V-ECUs, or complete V-ECU networks can be simulated and tested.

Software development processes for traditional automotive applications, such as drivetrain or braking systems, through to eDrive applications and functions for autonomous driving, can be made significantly faster via SIL tests through virtual testing and validation. In this way, a device under test (DUT) can be conveniently simulated on a computer; it can be linked to physically based models, and test scripts can be easily re-used later on hardware-in-the-loop (HIL) systems.

For SIL tests, complex simulation systems are generally created. These simulation systems usually include at least one target model, which is also referred to as a device under test (DUT) or system under test, plus environment and restbus models, which are needed for a meaningful simulation. In typical scenarios for creating such simulation systems, different teams are responsible for creating the models. In particular, these teams also work at different companies, resulting in particular confidentiality requirements.

Generally, therefore, the models that are to be tested are not created by the test team that creates the actual simulation system. The models to be tested typically also have many degrees of freedom in terms of the formal description and the external interfaces (ports and field buses). As a result, these models are not easy to incorporate into the simulation system, even if the interfaces are recorded in writing and/or graphically, for example in the form of a mock-up model.

In software development, a mock-up model (or simply a mock-up) refers to a reduced model of a piece of software to be created. Such mock-ups are used in particular in early development phases in order to represent user interface requirements when the client and contractor are collaborating. Mock-ups are usually a simple base structure of the operating-clement functions without any further functionality. Generally, no programming takes place; instead, the required functionalities and compatibilities are represented graphically.

Mock-up models are also used for module tests, i.e., for testing individual parts of a piece of software. In this case, mock-up objects are used as placeholders for objects that are needed for testing a different part and, for example, are not yet available at the start of development. In a later development stage, mock-up objects are used if, for example, the initialization of an existing, functional object is too complex or is not possible or not permitted in a test environment in the absence of a link to productive backend systems.

P. Juhlin, A. Karaagac, J.-C. Schlake, S. Grüner and J. Rückert, “Cloud-enabled Drive-Motor-Load Simulation Platform using Asset Administration Shell and Functional Mockup Units,” 2022 IEEE 27th International Conference on Emerging Technologies and Factory Automation (ETFA), Stuttgart, Germany, 2022, pp. 1-8, doi: 10.1109/ETFA52439.2022.9921678, describes how the development of complex installations or systems requires the individual installation models to be integrated and reviewed at system level. This requires relevant installation data and dynamic models of the individual installations to be integrated, and these may be developed by several providers using different design and simulation tools. This paper addresses the biggest challenges for the integration, namely the lack of interoperability between the corresponding data and simulation models, and the separate, inflexible application implementations, on the basis of a drive-motor-load system. The paper presents a drive-motor-load simulation platform with cloud capabilities that is based on the use of Asset Administration Shells (AAS) for automatic data exchange and functional mock-up units (FMUs) for the interoperable simulation, together with a first application of containerization for protecting components. The solution is intended to provide higher quality and efficiency of the engineering through simulation-based asset dimensioning, what-if simulations, and simulation-based calibration and optimization, as well as a flexible, user-friendly, and secure application provision. An AAS-based model integration for linking various domain models and their parameters in the areas of design, configuration, and virtual commissioning, including application-side load FMUs via AAS simulation submodels at integrated-system level, permits data interoperability and simultaneously serves as a building block for the digital twin of the future drive-motor-load system. The solution allows for various applications in different phases of the product life cycle, for example customer contact before sale (prompting), simulation-based calibration and construction optimization during development, progressive system validations and tests during virtual commissioning, and ongoing customer and OEM training during commissioning and operation.

J. Mezger, M. Ditze, M. Keckeisen, C. Kübler, V. Fäβler and B. Relovsky, “Protecting know-how in cross-organisational functional mock-up by a service-oriented approach with trust centres,” 2011 9th IEEE International Conference on Industrial Informatics, Lisbon, Portugal, 2011, pp. 628-633, doi: 10.1109/INDIN.2011.6034951, describes how, in digital product development in the automotive and aviation industries, the traditional digital mock-up (DMU) is soon to be expanded and replaced by the digital functional mock-up (DFMU). The DFMU adds functional aspects to the geometric integration of product models, as provided by the traditional DMUs. Thus, both the physical and the logic model properties can be studied. In addition, DFMUs form the basis for an integrated analysis of the holistic performance aspects of a product. The design of DFMUs is validated by a cost-efficient co-simulation—a method for simultaneously simulating individual components using various simulation tools that reciprocally exchange information in a collaborative way. This process can span many different organizations and thus requires cost-sensitive and confidential product models to be shared between suppliers and OEMs (buyers). This paper discusses using service-oriented architectures in co-simulation environments in order to improve the configuration process, protect the intellectual property of the model owners, and introduce electronic signatures for simulation models, data, and results. It also presents the concept of a functional mock-up trust center (FMTC), which implements some of these services. The FMTC is a practical and effective tool for safeguarding the intellectual property rights of model providers during co-simulation. This is achieved by the possibility of storing product models in an encrypted manner, as well as by a protected simulation environment.

Hatledal, Lars & Styve, Arne & Hovland, Geir & Zhang, Houxiang. (2019). A Language and Platform Independent Co-Simulation Framework Based on the Functional Mock-Up Interface. IEEE Access. pp. 1-1. 10.1109/ACCESS.2019.2933275, describes how the main goal of the functional mock-up interface (FMI) standard is to allow simulation models to be used jointly by different tools. To achieve this, FMI is based on a combination of XML files and compiled C-code packaged in a zip folder. This folder is referred to as a functional mock-up unit (FMU). An FMU can support a plurality of platforms in theory but not necessarily in practice. In addition, software libraries for interacting with FMUs may not be available in a particular language or platform. A further problem is the protection of intellectual property. While an FMU is free to make only the C-code in its binary form available, other resources within the FMU may not be protected. Distributing models in binary form also opens up the possibility of them containing malicious code. To overcome these challenges, this publication presents an FMI-based, open-source co-simulation framework that is language-and platform-independent owing to the use of established remote procedure call (RPC) technologies. One or more FMUs are packaged in a server program that supports one or more language-independent RPC systems via various network protocols. Together, they enable the cross-platform calling of FMUs from a plurality of languages, even ones that have not been supported so far. The client-server architecture allows intellectual property to be protected effectively while simultaneously providing a means for protecting users against malicious code.

### SUMMARY

In an example embodiment, the present invention provides a method for creating a rest model for a simulation system having a plurality of submodels. The method includes: selecting at least one submodel as a target model that is not to be included in the rest model; detecting ports of the simulation system that are to be linked to ports of the target model; creating ports in the rest model that correspond to the detected ports and have identical properties; detecting field buses of the simulation system that are to be linked to the target model; and creating field bus controllers in the rest model, wherein the field bus controllers correspond to the detected field buses.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 is a schematic illustration of the creation of a rest model for a simulation system having a plurality of submodels according to an example embodiment of the invention;

FIG. 2 shows an example of a simulation system;

FIG. 3 illustrates a reduction of the simulation system from FIG. 2 into a mock-up system according to an example embodiment of the invention;

FIG. 4 illustrates a reduction of the simulation system from FIG. 2 into an even further reduced mock-up system according to an example embodiment of the invention; and

FIG. 5 shows a flowchart for a method according to an example embodiment of the invention.

### DETAILED DESCRIPTION

Example embodiments of the invention provide an efficient method for creating a mock-up system for a simulation system, so that as little information as possible relating to the simulation system is disclosed by the mock-up model.

According to the invention, therefore, a method for creating a rest model for a simulation system having a plurality of submodels is provided, comprising the following method steps:
selecting at least one submodel as a target model that is not intended to be included in the rest model,
detecting ports of the simulation system that need to be linked to ports of the target model,
creating ports in the rest model that correspond to the detected ports and have identical properties,
detecting field buses of the simulation system that need to be linked to the target model, and
creating field bus controllers, which are suitable for the detected field buses, in the rest model.

According to example embodiments of the invention, a rest model is extracted from the simulation system and, from the perspective of the target model, behaves in the same way as the original simulation system in terms of content and the interfaces (ports and field buses). In other words, the rest model is a simplified model for the simulation system without the target model, the rest model only needing to have the functions that are required for testing the target model.

The term ‘interface’ is the umbrella term for the terms ‘ports’ and ‘field buses’. Here, the term ‘port’ refers to a data transfer point, and the term ‘field bus’ refers to modeled communication hardware. Ports thus constitute an interface for transmitting data. The mechanism by which these data are transmitted can be, for example, a jointly used memory area, a function call, or direct cable links. Moreover, it can also be a 1:n link running from port to port. Field buses can also be mapped with ports, and particular properties that characterize each field bus can be assigned to said ports. Field buses have an important role, especially in automotive software and distributed systems, so in this case the field buses are treated as distinct interfaces.

In the present case, the term ‘field bus controller’ generally refers to an access point that maps the functions of one or more controllers for a field bus. Field bus controllers are thus used to enable and manage communication between different field devices such as sensors, actuators, and control units. Therefore, field buses comprise communication protocols that are used to permit the control of the various components and the exchange of information. A field bus controller thus allows communication to be coordinated centrally by organizing and controlling the exchange of data between the field devices. In this case, the field bus controller can receive and process data and send them to the corresponding devices. This allows corresponding processes to be controlled in real time and monitored.

If, in the present case, suitable field bus controllers for the detected field buses are generated in the rest model, then this means that the generated field bus controllers are configured such that, by using them, communication between field devices connected via the detected field buses can be controlled in the above-described manner.

The invention can be used for different kinds of ports. According to a preferred development of the invention, however, the ports comprise at least one communications port. The properties of the ports can include different kinds of data. According to a preferred development of the invention, however, the properties of the ports include names, frequency of transmission, data width, and/or type data. In addition, it is provided according to a preferred development of the invention that non-detected ports and field bus controllers of non-detected field buses are not incorporated into the rest model.

The invention is based on the fact that the rest model still has at least one submodel with which the target model to be developed has to be compatible. Typically, however, the rest model has a plurality of submodels. In this regard, it is provided according to a preferred development of the invention that the method additionally comprises the following method steps when the rest model has a plurality of submodels:
merging the submodels in the rest model to form a single model having the same semantics.

Preferably, in this case, merging the submodels in the rest model to form a single model having the same semantics comprises the following method steps:
adopting implementations of the submodels in the rest model, which each have the same functions as the submodels in the original simulation system,
generating code for communication links between the submodels of the rest model, and
providing the generated code in the rest model, and
setting up forwarding of calls from the target model to the rest model, to the implementations of the submodels in the rest model.

If at least one submodel has periodic calls, the following method steps are provided according to a preferred development of the invention:
forming a superset of a time frame of the calls, and
transferring the calls into time frames of the rest model.

In this regard, the following method step is preferable:
creating a predetermined order for calling the implementations of the submodels in the rest model.

In this case, the order is preferably selected to be statically sequential or parallel or to be the same as the order in the original simulation system.

In addition, it has proven beneficial, and is thus preferable, that in the event that the submodels each have their own variable description, the variable descriptions of the submodels are merged to form a joint variable description such as to allow the variables in the rest model to be measured and stimulated (e.g., the variables may be read or the value of the variable may be overwritten) on the basis of said joint variable description. In this case, real names are preferably concealed.

In addition, the following method step is provided as a final method step according to a preferred development of the invention:
linking the target model to the rest model such that the resulting simulation system behaves like the original simulation system.

The invention will be explained in more detail below on the basis of a preferred embodiment example with reference to the drawings, in which:

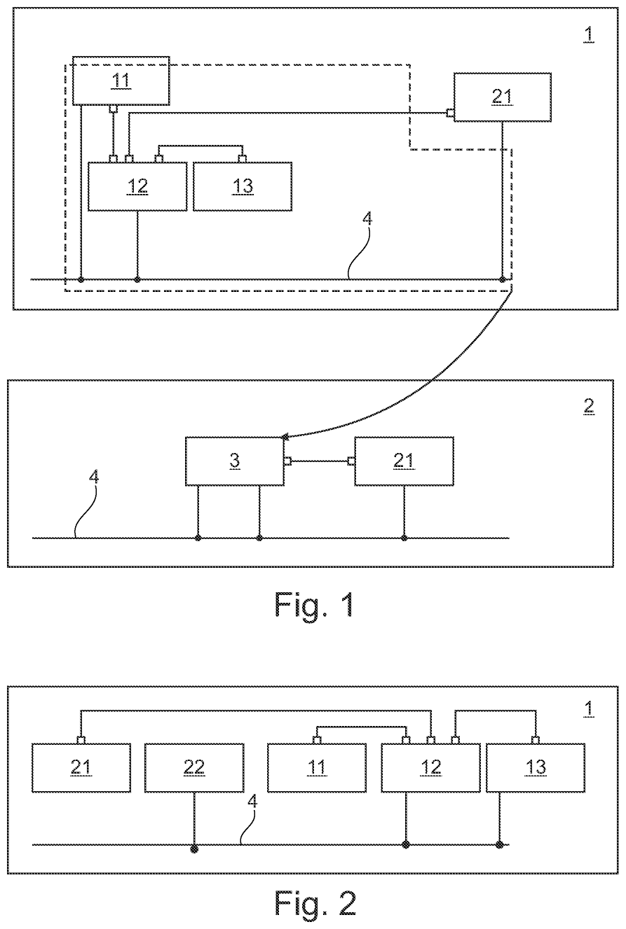

FIG. 1 is a schematic and general illustration of the creation of a rest model 3 for a simulation system 1 having a plurality of submodels 11, 12, 13, 21 according to an example embodiment of the invention. The submodels 11, 12, 13, 21 are linked together via bus communication links 4. A submodel 21 is selected as a target model 21, and all the other submodels 11, 12, 13 that are in communication with the target model 21 are transferred into the rest model 3, as shown in FIG. 1 by the curved arrow.

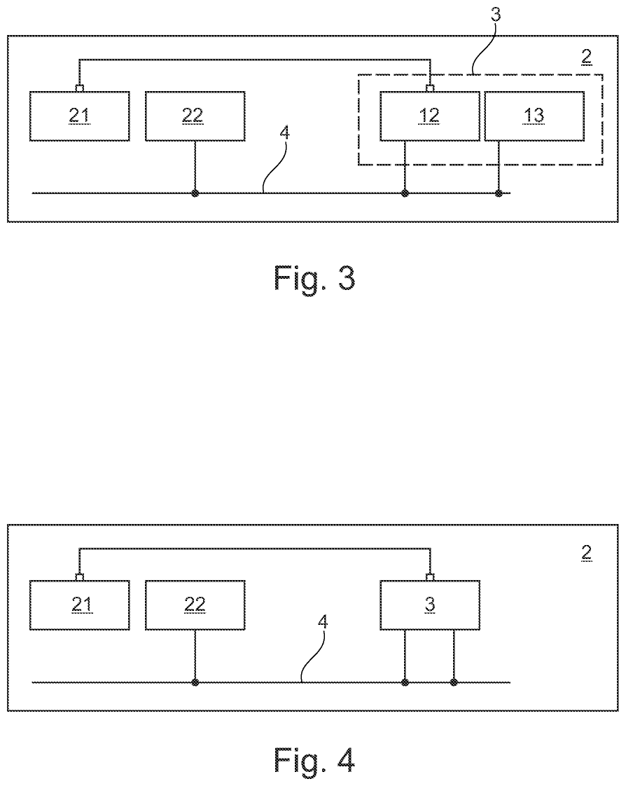

In this way, it is also possible, for example, for a simulation system 1 to be configured as shown in FIG. 2 and then transferred into a mock-up system 2 as shown in FIG. 3 or FIG. 4. In this case, the simulation system 1 has five submodels 11, 12, 13, 21, 22, two of which are selected as target models 21, 22 that are not intended to be included in the rest model 3. Since the submodel 11 is now only linked to the submodel 12 and does not communicate with the two target models 21, 22, the submodel 11 can be left out when creating the mock-up system 2, without this rendering it difficult or even impossible to test the target models 21, 22 via the mock-up system 2. This is illustrated in FIG. 3. Here, the rest model 3 is effectively the model group that has been reduced to the submodels 12, 13.

FIG. 4 shows that, in addition, a further reduction can be carried out in the mock-up model 2 by transferring the submodels 12, 13 into a rest model 3 in which certain details of the submodels 12, 13 that are not critical for interoperability with the target models 21, 22 are concealed externally.

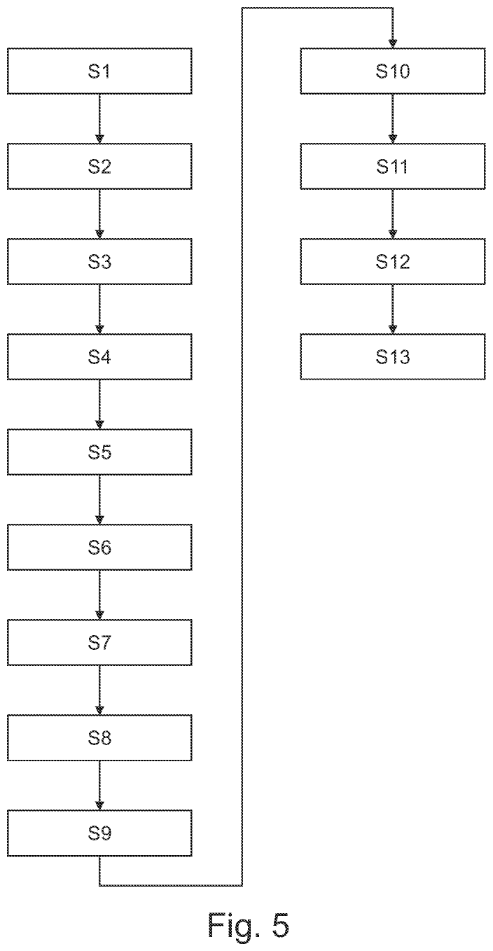

Following this general description, an example method sequence according to an example embodiment of the invention will be explained below on the basis of FIG. 5. This is a method for creating a rest model 3 for a simulation system 1 having a plurality of submodels 11, 12, 13, 21, 22, as shown in FIG. 2, for example, comprising the following method steps:
S1) selecting at least one submodel 11, 12, 13, 21, 22 as a target model 21, 22 that is not intended to be included in the rest model 3,
S2) detecting ports of the simulation system 1 that need to be linked to ports of the target model 21, 22,
S3) creating ports in the rest model 3 that correspond to the detected ports and have identical properties,
S4) detecting field buses of the simulation system 1 that need to be linked to the target model 21, 22, and
S5) creating field bus controllers, which are suitable for the detected field buses, in the rest model 3.

In this case, the ports comprise communications ports for the submodels 11, 12, 13, 21, 22 to communicate with one another, and the names, frequency of transmission, data width, and type data of the ports are taken into account as the properties thereof. In the process, however, non-detected ports and field bus controllers of non-detected field buses are also not incorporated into the rest model 3.

In the preferred embodiment example of the invention being described here, the rest model 3 has a plurality of submodels 12, 13, namely two submodels. In this situation with a plurality of submodels 12, 13 for the rest model 3, the submodels 12, 13, as shown in FIG. 3, in the rest model 3 can be merged to form a single model having the same semantics, wherein merging the submodels 12, 13 in the rest model 3 to form a single model having the same semantics comprises the following method steps:
S6) adopting implementations of the submodels 12, 13 in the rest model 3, which each have the same functions as the submodels 12, 13 in the original simulation system 1,
S7) generating code for communication links between the submodels 12, 13 of the rest model 3, and providing the generated code in the rest model 3, and
S8) setting up forwarding of calls from the target model 21, 22 to the rest model 3, to the implementations of the submodels 12, 13 in the rest model 3.

In the present case, the submodels 12, 13 have periodic calls, so the following method steps come next:
S9) forming a superset of a time frame of the calls,
S10) transferring the calls into time frames of the rest model 3, and
S11) creating a predetermined order for calling the implementations of the submodels 11, 12, 13 in the rest model 3.

In this case, the order can be selected to be statically sequential or parallel or to be the same as the order in the original simulation system 1.

In the example embodiments of the invention being described here, the submodels 12, 13 furthermore each have their own variable description. Thus, method step S12) is provided, in which the variable descriptions of the submodels 12, 13 are merged to form a joint variable description such as to allow the variables in the rest model 3 to be measured and stimulated (e.g., overwritten) on the basis of said joint variable description. In this case, the real names of the variables are concealed via a computer program.

The method ends with the final method step S13), in which, as shown in FIG. 4, the target models 21, 22 are linked to the rest model 3 such that the resulting mock-up system 2 behaves like the original simulation system 1 and can be used for corresponding tests.

In the example embodiments of the invention being described in the present case, only those submodels 12, 13 that have a direct link to the target models 21, 22 are included in the rest model 3 of the mock-up system 2. Moreover, only those link points (ports, buses) that have a direct link to the target models 21, 22 are included in the rest model 3. When transferring the submodels 12, 13 into a single model, a link script ensures that the links are still correctly selected. In addition, no real names are used for link points and submodels. Here too, a link script ensures that the links are still correctly selected. In this case, the entirety of the communication data for the first time steps is recorded and transferred into the mock-up system 2 in an automated manner as behavior.

By virtue of this method, manufacturers, i.e., buyers of the target systems 21, 22, can define an acceptance test for a supplier of the target systems 21, 22 using the mock-up system 2, which ensures that the supplied target models 21, 22 can be incorporated into the simulation system 1 without any manual work involved. This is advantageous in cloud scenarios; suppliers are provided with the mock-up system 2 on site outside the cloud in order to render their target models 21, 22 executable. If the supplier is certain, by way of the mock-up system 2, that the model can be successfully integrated in the test cloud, this not only saves time but also provides assurance on both sides regarding operations. Successful commissioning using the mock-up system 2 can also be set as a criterion for when a target model 21, 22 is accepted by the buyer. Using a corresponding ‘seal’, the target models 21, 22 can then be transmitted to the buyer's cloud, and the target models 21, 22 are automatically adopted in corresponding tests without the buyer disclosing details of their test.

If the real names or the simulation topology are concealed, in the present case the real names are replaced with a randomly generated identifier before the mock-up system 2 is created. The link information is retained and protected. As a result, the same link can be reproduced in the mock-up system 2 without the topology of the simulation system 1 being known.

It will be appreciated that the interfaces between the mock-up and the remaining system parts are not arbitrarily chosen. They model, for example, the connections of the system in the real car. There are different options for communication between the system parts to match the communication hardware. Also, the system parts may resemble directly hardware in a car and physics interacting with the car. The point is not that the system parts somehow represent hardware, but their interfaces match the hardware, so it can be used also later in a HIL test.

It will further be appreciated that example embodiments of the invention make it easy to keep the interfaces that are relevant, while filtering out the connections and hardware instances that not relevant for a respective use case while still getting the same result. This secures the correctness of the hardware.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

1 Simulation system
2 Mock-up system
3 Rest model
4 Bus communication links
11 Submodel
12 Submodel
13 Submodel
21 Target model
22 Target model

1. A method for creating a rest model for a simulation system having a plurality of submodels, the method comprising:
receiving, by a computing device, a selection of at least one submodel as a target model that is not to be included in the rest model;
detecting, by the computing device, ports of the simulation system that are to be linked to ports of the target model;
creating, by the computing device, ports in the rest model that correspond to the detected ports and have identical properties;
detecting, by the computing device, field buses of the simulation system that are to be linked to the target model; and
creating, by the computing device, field bus controllers in the rest model, wherein the field bus controllers correspond to the detected field buses.

2. The method according to claim 1, wherein the ports comprise at least one communications port.

3. The method according to claim 1, wherein the properties include names, frequency of transmission, data width, and/or type data.

4. The method according to claim 1, wherein non-detected ports and field bus controllers of non-detected field buses are not incorporated into the rest model.

5. The method according to claim 1, wherein the rest model has a plurality of submodels, and wherein the method further comprises:
merging the submodels in the rest model to form a single model.

6. The method according to claim 5, wherein merging the submodels comprises:
adopting implementations of the submodels in the rest model, which each have the same functions as the submodels in the original simulation system;
generating code for communication links between the submodels of the rest model, and providing the generated code in the rest model; and
setting up forwarding of calls from the target model to the rest model, to the implementations of the submodels in the rest model.

7. The method according to claim 6, wherein at least one submodel has periodic calls, and wherein the method further comprises:
forming a superset of a timeframe of the calls; and
transferring the calls into timeframes of the rest model.

8. The method according to claim 6, further comprising:
creating a predetermined order for calling the implementations of the submodels in the rest model.

9. The method according to claim 8, wherein the order is selected to be statically sequential or parallel or to be the same as the order in the original simulation system.

10. The method according to claim 1, wherein each of the submodels has a respective variable description, and the respective variable descriptions of the submodels are merged to form a joint variable description.

11. The method according to claim 1, further comprising:
linking the target model to the rest model.

12. A non-transitory computer-readable medium having processor-executable instructions stored thereon for creating a rest model for a simulation system having a plurality of submodels, wherein the processor-executable instructions, when executed, facilitate performance of the following:
selecting at least one submodel as a target model that is not to be included in the rest model;
detecting ports of the simulation system that are to be linked to ports of the target model;
creating ports in the rest model that correspond to the detected ports and have identical properties;
detecting field buses of the simulation system that are to be linked to the target model; and
creating field bus controllers in the rest model, wherein the field bus controllers correspond to the detected field buses.
